(19) United States
(12) Patent Application Publication
(10) Pub. No.: US 2016/0293502 A1
(43) Pub. Date: Oct. 6, 2016

(54) METHOD AND APPARATUS FOR DETECTING DEFECTS ON WAFERS

(71) Applicant: Lam Research Corporation, Fremont, CA (US)

(72) Inventor: David Pirkle, Soquel, CA (US)

(21) Appl. No.: 15/083,039

(22) Filed: Mar. 28, 2016

Related U.S. Application Data
(60) Provisional application No. 62/141,162, filed on Mar. 31, 2015.

(51) Int. Cl. H01L 21/66

(52) U.S. Cl. CPC H01L 22/24; H01L 22/12

(57) ABSTRACT

Methods and apparatuses for detecting particle defects on partially fabricated semiconductor wafers using chemical markers capable of binding to defects that are not detectable by laser diffractometry are provided herein.

### CROSS-REFERENCE TO RELATED APPLICATION

This application claims benefit of U.S. Provisional Patent Application No. 62/141,162, filed Mar. 31, 2015, and titled “METHOD AND APPARATUS FOR DETECTING DEFECTS ON WAFERS,” which is incorporated by reference herein in its entirety and for all purposes.

### BACKGROUND

Techniques for detecting defects on wafers in semiconductor fabrication processes are used to evaluate the quality of the fabrication processes. Such techniques involve identifying defects across the surface of a partially fabricated semiconductor substrate and identifying the composition of such defects to help determine the origin of the defect.

### SUMMARY

Provided herein are methods and apparatuses for detecting defects on a semiconductor wafer. One aspect involves a method of detecting defects of a partially fabricated semiconductor wafer for semiconductor devices, the method including: exposing the partially fabricated semiconductor wafer to a first chemical marker capable of selectively binding to particle defects disposed on the partially fabricated semiconductor wafer surface, undetectable by laser diffractometry and having a first composition, the chemical marker including a component capable of detection when exposed to a stimulant; after exposing the wafer to the chemical marker, exposing the partially fabricated semiconductor wafer to the stimulant to form detectable areas of the partially fabricated semiconductor wafer where the first chemical marker is selectively bound to the particle defects; and detecting the detectable areas on the surface of the partially fabricated semiconductor wafer, whereby the surface of the partially fabricated semiconductor wafer includes less than about 2000 defects. In various embodiments, the surface of the partially fabricated semiconductor wafer includes less than about 50 defects. In some embodiments, the partially fabricated semiconductor wafer is a 300-mm wafer.

In various embodiments, the partially fabricated semiconductor wafer is exposed to the first chemical marker in an aqueous bath including the first chemical marker.

The diameter of the particle defects may be less than about 20 nm. In some embodiments, the diameter of the particle defects is less than 10 nm.

The method may further include exposing the partially fabricated semiconductor wafer to a second chemical marker selective to particle defects having a second composition to bind the second chemical marker to the particle defects having the second composition. In some embodiments, the first chemical marker emits a first spectral distribution of illumination when exposed to the stimulant, and the second chemical marker emits a second spectral distribution of illumination different from the first spectral distribution of illumination when exposed to the simulant. In some embodiments, the first spectral distribution of illumination is a color in the visible spectrum and the second spectral distribution of illumination is another color in the visible spectrum.

In some embodiments, exposing the partially fabricated semiconductor wafer to the first chemical marker and exposing the partially fabricated semiconductor wafer to the second chemical marker includes immersing the partially fabricated semiconductor wafer in an aqueous bath including the first chemical marker and the second chemical marker.

In some embodiments, exposing the partially fabricated semiconductor wafer to the first chemical marker and exposing the partially fabricated semiconductor wafer to the second chemical marker includes delivering an aerosol spray of a solution including the first chemical marker and the second chemical marker to a chamber housing the partially fabricated semiconductor wafer.

In various embodiments, the method may include further include modifying a process recipe for fabricating the partially fabricated semiconductor wafer to reduce particle defects in the detectable areas of the partially fabricated semiconductor wafer.

In some embodiments, the compound of the first chemical marker is a fluorescent dye. The stimulant may be, in some embodiments, a light having a wavelength of less than 450 nm.

In some embodiments, the first chemical marker is a gas. In various embodiments, the chemical marker is a genetically engineered peptide with binding specificity for inorganic materials.

Another aspect involves an apparatus for detecting defects on a partially fabricated semiconductor wafer, the apparatus including: a detection chamber including a wafer holder for holding the partially fabricated semiconductor wafer in the detection chamber; an inlet for delivering a chemical marker to the detection chamber; an illumination source for stimulating the chemical marker to emit light; a detector for detecting emissions of the chemical marker on the surface of the partially fabricated semiconductor wafer; and a controller for controlling operations of the apparatus, the controller including machine-readable instructions for: introducing the chemical marker to the detection chamber via the inlet; removing excess chemical marker from the detection chamber after introducing the chemical marker to the detection chamber; and turning on the illumination source to illuminate the chemical marker. In some embodiments, the stimulant is an illumination source.

In various embodiments, the apparatus may further include a tracking device oriented for detecting the wafer surface while the wafer is held on the wafer holder; and a wafer imaging system including image analysis logic for detecting illuminated chemical markers on the wafer surface using properties of the illuminated chemical markers. In various embodiments, the wafer imaging system further includes a feedback mechanism for modifying process recipes in response to data collected from the tracking device. In some embodiments, the properties include a spectral distribution of illumination. In some embodiments, the spectral distribution of illumination is a color. In some embodiments, the properties include brightness.

In various embodiments, the apparatus also includes a wafer transfer tool for inserting and removing a wafer from the detection chamber.

The apparatus may be integrated with a semiconductor device fabrication apparatus, the semiconductor device fabrication apparatus including one or more process chambers for processing semiconductor wafers and the wafer transfer tool.

In various embodiments, the inlet is capable of delivering an aqueous solution including the chemical marker to the detection chamber.

In some embodiments, the inlet is capable of delivering an aerosol spray of the chemical marker to the detection chamber to contact the wafer with the chemical marker, and the inlet is positioned over the top surface of the wafer.

In some embodiments, the detection chamber is capable of containing an aqueous bath including one or more chemical markers and the wafer holder is capable of immersing the wafer in the aqueous bath.

In some embodiments, the apparatus further includes a chemical source, the chemical source including a compound capable of modifying a chemical marker to generate a detectable chemical marker.

These and other aspects are described further below with reference to the drawings.

### BRIEF DESCRIPTION OF THE DRAWINGS

FIG. 1 is a process flow diagram depicting operations of a method performed in accordance with certain disclosed embodiments.

FIG. 2 is a schematic illustration of an example chamber suitable in accordance with certain disclosed embodiments.

FIG. 3 is a schematic illustration of an example chamber suitable in accordance with certain disclosed embodiments.

FIG. 4 is a schematic diagram of an example process apparatus for performing disclosed embodiments.

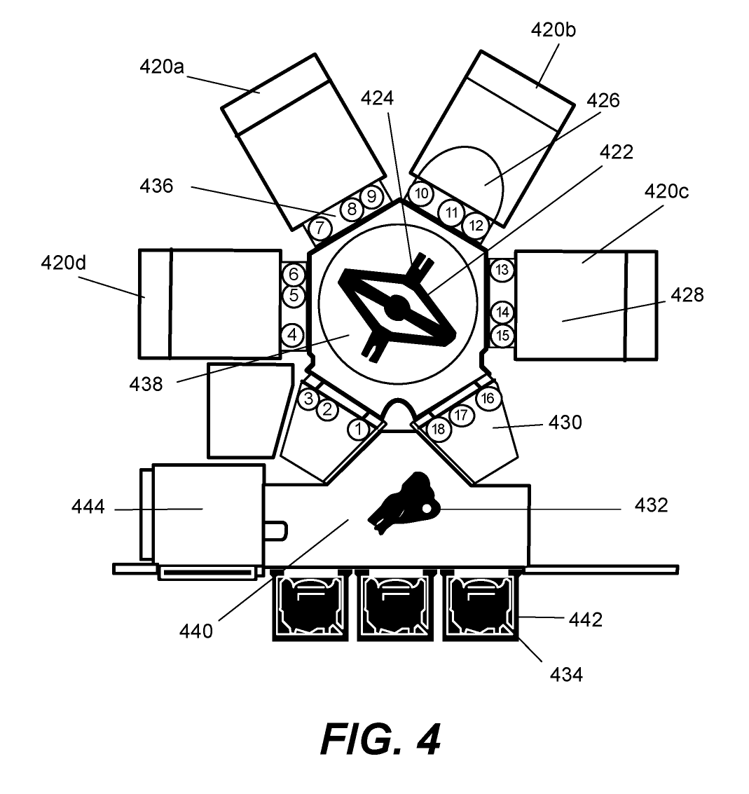

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Surface defects such as particles and pits affect the yield of several commercial processes, such as semiconductor manufacturing, memory disk manufacturing, and flat panel display manufacturing. Some commercial industrial processes include detection of surface defects in a coating process, such as coating a large sheet of stainless steel. In such cases, surface defects may be pinholes or compositional defects detectable by granulometric techniques, such as laser diffractometry. However, unlike such applications, in semiconductor processing, the tolerable density of defects (e.g., the amount of defects that may be found over the area of the semiconductor wafer) is less than about 50 defects over the surface of the wafer. It is desirable to fabricate a semiconductor wafer having 0 defects over the surface of the wafer. As a result, detection and identification of surface defects, and in particular particle defects, in semiconductor manufacturing presents many challenges.

In semiconductor manufacturing, defects are reduced through improvements in semiconductor substrate processing, such as modifications to deposition and etching processes. The term “substrate” or “wafer” as used herein may refer to a partially fabricated semiconductor substrate or a partially fabricated semiconductor wafer. Historically, in semiconductor processes, the presence of smaller defects had minimal effects on substrate quality. However, as technology progresses, the size of defects which are “yield killers” (e.g., that substantially affect the quality of fabricated semiconductor wafers) has decreased dramatically. Small defects in small device fabrication have become a greater problem as the effect the defects have on the device is more pronounced. As a result, eliminating the presence of smaller defects is desired to improve substrate quality and prevent device failure.

“Defects” as described herein include particle defects. Defects on semiconductor substrates may originate from multiple sources. For example, defects may result from the many components in a substrate processing chamber. A substrate processing chamber may have components such as showerheads, chamber walls, seals, and windows. The materials of the showerheads, chamber walls, and the windows, or materials accumulating on chamber components in prior operations, may each be “shed,” in the form of particles, onto a substrate, causing defects. Additionally, some fabrication processes such as etching processes may result in redeposition or residue left on the substrate, thereby causing defects.

Current defect detection techniques can determine the number of defects and their location, if the defects are large enough to be detected, using granulometric techniques, such as laser diffractometry. For example, substrate defects are detected with tools that may have detection thresholds that are determined by a number of design factors. An example tool may be a laser metrology tool. Such tools may include detection thresholds with minimum size thresholds, where a defect below the minimum size threshold may not be detected. The minimize size threshold may vary for defects and/or substrates of different compositions. For example, some laser techniques may not detect defects that are less than 20 nm in size.

One example conventional tool is a laser metrology tool, which uses a probe laser that projects a beam onto a substrate. The beam reflects off the substrate and the reflections are analyzed to determine if a defect exists in the region of the substrate that the beam was projected onto. This technique may also be used to detect contrast differences in the image containing the defect with a “known good” reference image.

For several relevant manufacturing processes, yield-killer defects are smaller than the wavelength of most light sources, and the signal from the defect is too small to be detectable or only detectable if the illuminating light source is so intense that it starts to interact negatively with the material being inspected (overheating or ablation of surface material). This approach does not have a roadmap to detect ever smaller defects. Further, in order to detect defects of smaller sizes, the laser power, called fluence, is increased. As fluence is increased, the possibility of substrates or defects being damaged, or ablated, by the more powerful laser beam also increases.

If defects are identified in a specific location on a substrate, the substrate is conventionally then subject to processing with x-ray spectroscopy techniques to determine the chemistry of the defect, which may provide information as to the origin of the defect (e.g., whether the defect is a material shed from the chamber components or whether the defect is a material deposited as a result of fabrication processes).

Identifying the composition of the defect may be useful to trace back the defects to their source, thus allowing for further improvements in reducing the defect count of substrates. However, current techniques provide very limited information about the nature of the defect (size, material composition, shape). A separate “Review Process” may sometimes be implemented utilizing Scanning Electron Microscopy (SEM) to obtain this information. Review tools are large and expensive, and review processes are time consuming.

Provided herein are methods and apparatuses for detecting particle defects on a semiconductor wafer undetectable by laser diffractometry. In particular, methods and apparatuses are suitable for detecting such particle defects smaller than the minimum size threshold of a laser metrology tool, such as smaller than about 20 nm. Disclosed embodiments for detecting particle defects smaller than a given minimum size threshold involves marking the defects with a chemical marker that can itself be detected according to processes not limited by the light-based direct defect detection techniques. Suitable chemical markers are capable of binding to particle defects that are not detectable by techniques such as laser diffractometry. In one example, a chemical marker that can fluoresce when exposed to certain conditions may be used in some embodiments.

Disclosed embodiments involve exposing a wafer containing defects to a chemical marker having molecular components that preferentially adhere to the defects, such as particle defects. The chemical marker may, in some embodiments, be a polymer or protein. In addition, the chemical marker may include molecular components which, when subject to a stimulant, are then detectable by observation or spectroscopy. One example is a chemical with molecular components which fluoresce brightly when exposed to the proper illumination. The exposed wafer is illuminated properly to cause the chemical marker to fluoresce, while being observed at high magnification to precisely monitor the location of the fluorescing chemical.

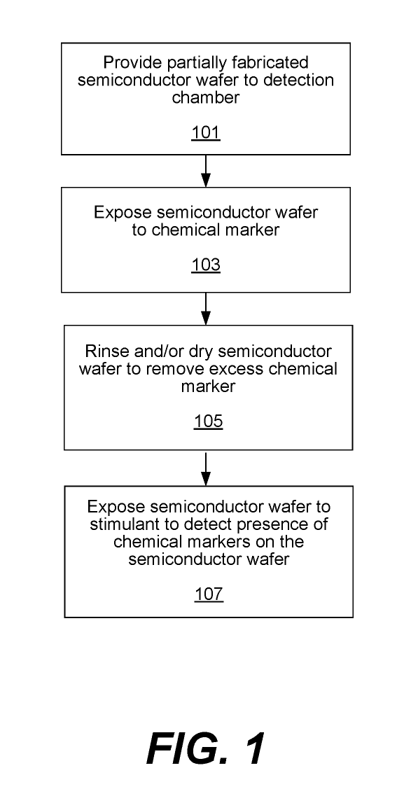

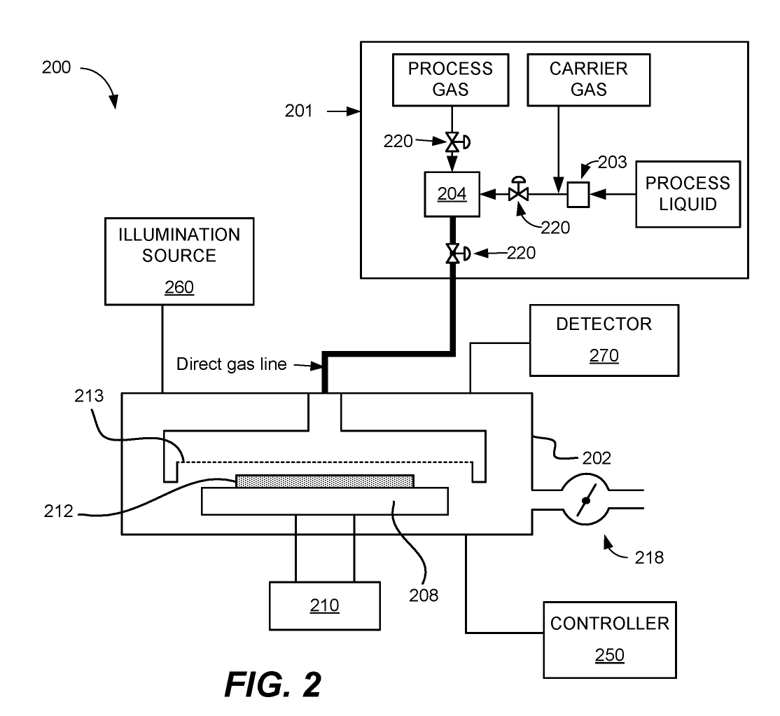

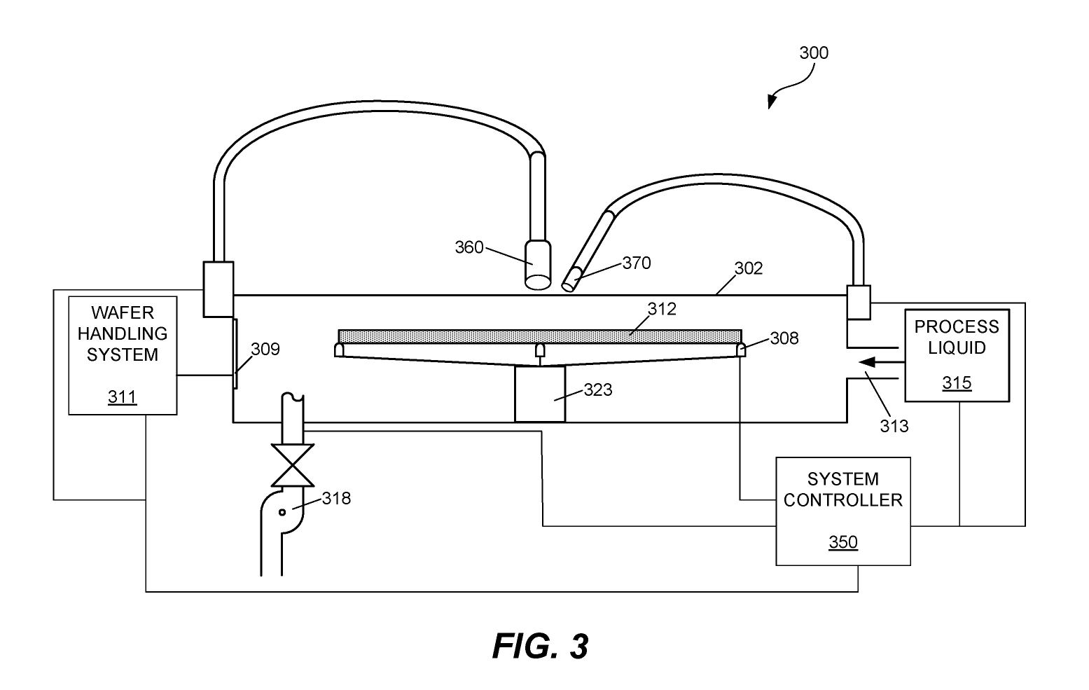

FIG. 1 provides a process flow diagram depicting operations that may be performed in a method in accordance with certain disclosed embodiments. In operation 101, a wafer having particle defects is provided to a detection chamber. Example detection chambers are depicted in FIGS. 2 and 3, which are further described below.

In various embodiments, the wafer may be a semiconductor substrate, such as a partially fabricated semiconductor substrate. The substrate may be a silicon wafer, e.g., a 200-mm wafer, a 300-mm wafer, or a 450-mm wafer, including wafers having one or more layers of material, such as dielectric, conducting, or semi-conducting material deposited thereon. Substrates may have “features” such as via or contact holes, which may be characterized by one or more of narrow and/or re-entrant openings, constrictions within the feature, and high aspect ratios. Non-limiting examples of under-layers include dielectric layers and conducting layers, e.g., silicon oxides, silicon nitrides, silicon carbides, metal oxides, metal nitrides, metal carbides, and metal layers.

In some embodiments operation 101 involves providing a partially fabricated semiconductor wafer to a detection chamber, where the wafer includes particle defects. For example, in some embodiments, the partially fabricated semiconductor wafer may include particle defects having sizes less than about 20 nm. In some embodiments, the diameter of particle defects is less than about 20 nm. In some embodiments, the diameter of particle defects is less than about 10 nm. In some embodiments, the partially fabricated semiconductor wafer may have a defect density of about 2000 defects or less than about 50 defects over the surface of the wafer. The particle defects on the partially fabricated semiconductor wafer may be of any composition, including silicon oxide, silicon nitride, silicon carbide, metal oxide, metal, metal nitrides, metal carbides, and carbon-containing materials.

Returning to FIG. 1, in operation 103, the wafer is exposed to a chemical marker. In some embodiments, operation 103 involves exposing a partially fabricated semiconductor wafer to a chemical marker capable of selectively binding to particle defects disposed on the partially fabricated semiconductor wafer surface.

Chemical markers may be configured to adhere to particular defects (particular materials, particular shapes) and the apparatus can be configured to record that information. For example, in some embodiments, chemical markers may be configured to adhere to particle defects of particular materials (e.g., a chemical marker that selectively binds to silicon oxide). In some embodiments, chemical markers may be configured to adhere to particle defects of particular shapes (e.g., a chemical marker that selectively binds to round particle defects). An apparatus in accordance with disclosed embodiments may be configured to record this information. For example, the apparatus may be configured to record the types of chemical markers and the material the markers selectively bind to.

As previously noted, in some embodiments, chemical marker molecules may be capable of selectively binding to specific types of inorganic atoms or compounds. For example, a chemical marker may bond to inorganic atoms or compounds by reacting in a chemical reaction to form covalent bonds, form an ionic bond, or combinations thereof. In some embodiments, chemical markers may include genetically engineered peptides for inorganic compounds. In some embodiments, chemical markers may include an inorganic or organic cofactor capable of binding to inorganic compounds such as metals. An example cofactor may be nicotinamide adenine dinucleotide phosphate (NADP⁺). Enzymes capable of binding to such co-factors may then be used to identify and locate defects. In some embodiments, defects are detected by fluorescence, bioluminescence, chemiluminscence, radioisotopes, and other mechanisms. In some embodiments, a chemical marker may be selected such that it selectively binds to a certain material and the fluorescence color associated with that marker identifies the material. In some embodiments, chemical markers may be selected which includes more than one molecular component, each of which emits a different color, such that when it binds to a first material a first color is emitted, and when it binds to a second material, a second color is emitted.

Chemical markers may include one or more molecular components that exhibit one or more properties when attached to different types of materials. For example chemical markers may include molecular components that emit one color when exposed to a stimulant such as a light. In some embodiments, the color may be any spectral distribution of illumination and may not be limited to the visible spectrum. In some embodiments, the chemical marker includes a component capable of detection when exposed to a stimulant.

In some embodiments, a mixture of chemical markers may be used such that the mixture includes sets of chemical markers, each set capable of attaching to different types of materials and capable of emitting different colors, such that when the marked wafer is observed, different colors may be associated with specific compositions of each defect. For example, a wafer may be exposed to a mixture of a first and second chemical marker, where the first chemical marker binds selectively to silicon oxide and the second chemical marker binds selectively to silicon nitride. The first chemical marker may include a molecular component that emits a red light when exposed to a stimulant while the second chemical marker may include a molecular component that emits a green light when exposed to a stimulant. In some embodiments, the chemical markers may emit their corresponding lights when exposed to the same stimulant. In some embodiments, the chemical markers may emit their corresponding lights when exposed to a particular stimulant such that only the first chemical marker emits light when exposed to a first stimulant but not when exposed to a second stimulant, while only the second chemical marker emits light when exposed to the second stimulant but not when exposed to the first stimulant.

Apparatuses in accordance with disclosed embodiments may be capable of noting the number of defects detected and the location of the defects as well as the emitted color(s) of chemical markers when subjected to a stimulant. Defect size may be determined by the brightness or intensity of the fluorescence or emitted light from a chemical marker, where the brightness is proportional to the number of chemical marker molecules, by calculating the number of chemical markers adhering to the defect.

The disclosed embodiments solve the problem of detecting ever smaller defects by utilizing a chemical marker to “find” and adhere to the defect. Even one molecule of the chemical marker may provide detection capability, so the minimum detectable defect size is limited the properties of the chemical marker (e.g., able to attach to one atom of defect), which can be engineered, rather than to the properties of the defect. For example, in some embodiments, a chemical marker may be fabricated such that it is capable of detecting particle defects less than 20 nm in size.

In performing disclosed embodiments, defect detection is not dependent on particle size but rather dependent on properties of a chemical marker, such that more information about the nature of the defects can be assessed. In disclosed embodiments, different chemical markers can bind to different defect types, and are capable of binding to very small defects. Methods provide information on defect type without performing SEM Review. In disclosed embodiments, defects are detected based on their interaction with the chemical marker, not based on their interaction with photons.

One example of a chemical marker is a genetically engineered peptide with binding specificity for inorganic materials (“GEPI”). GEPIs may be a peptide including amino acids that bind to an inorganic compound. In some embodiments, GEPIs may be configured to bind to some inorganic compounds selective to other inorganic compounds. GEPIs may include a compound that may fluoresce when exposed to light.

In various embodiments, during operation 103, the chemical marker is delivered to the detection chamber housing the wafer using an aerosol spray. The chemical marker may be delivered using a showerhead over the wafer such that the wafer is exposed to an even amount of the chemical marker over the wafer. The duration for exposing the wafer to the chemical marker may depend on the chemical marker and the wafer, as well as the composition of the particle defects being detected. The wafer may be exposed to a chemical marker aerosol spray for a duration between about 10 and about 20 seconds.

In various embodiments, operations 101 through 107 may be repeated in cycles such as a first cycle involves exposing the wafer to a first chemical marker during operation 103 and a second cycle involves exposing the wafer to a second chemical marker during the repeated operation 103. In some embodiments, operation 103 in a single cycle involves first exposing the wafer to a first chemical marker and then exposing the wafer to a second chemical marker, etc. In various embodiments the order of the chemical marker exposures may vary from cycle to cycle or may be the same in each cycle. In some embodiments, the order of the chemical marker exposures may be used to modulate the selectivity of the binding of the first chemical marker as opposed to the second chemical marker such that material more likely to bind only to the first chemical marker and less likely to bind to (though possibly capable of binding to) the second chemical marker is first exposed to the first chemical marker to bind to the first.

In operation 105, the semiconductor wafer is rinsed or dried to remove excess chemical marker from the surface, such that only chemical markers that are selectively bound to particle defects remain on the surface of the substrate. In various embodiments, operation 105 may be optional. In some embodiments, operation 105 may be performed by delivering a rinsing solution, such as deionized water, to the detection chamber to remove the excess chemical marker. The solution may then be pumped from the detection chamber. In some embodiments, operation 105 may be performed by draining an aqueous solution of the chemical marker from the detection chamber.

In operation 107, the semiconductor wafer is exposed to a stimulant to detect presence of chemical markers on the surface of the semiconductor wafer. In some embodiments, a partially fabricated semiconductor wafer may be exposed to the stimulant after exposing the wafer to the chemical marker to form detectable areas of the partially fabricated semiconductor wafer where the chemical marker is selectively bound to the particle defects. Operation 107 may further include detecting the detectable areas on the surface of the partially fabricated semiconductor wafer, such as determining the location, brightness, color, or other property of the detectable areas.

In various embodiments, the stimulant is a light or illumination source. For example, if the chemical marker includes a fluorescent dye, the stimulant such as a light or illumination source is used to cause the fluorescent dye to fluoresce such that a detection system and/or camera may be used to detect the fluorescing or stimulated chemical marker. In some embodiments, the stimulant may be a light having a wavelength of less than 450 nm. In some embodiments, the stimulant is a chemical source including a compound capable of modifying a chemical marker to generate a detectable chemical marker.

In various embodiments, where more than one chemical marker is used, each chemical marker may bind selectively to particle defects of different compositions. For example, a chemical marker A may selectively bind to silicon oxide defects, while chemical marker B may selectively bind to silicon nitride defects. In various embodiments, these chemical markers may emit different colors or different wavelengths of light when exposed to a stimulant. For example, in some embodiments, chemical marker A may emit a red color when exposed to illumination while chemical marker B may emit a blue color when exposed to the same illumination. Thus, based on the detected colors, one can identify the chemical compositions of the particle defects without subsequent processing such as x-ray spectroscopy.

In some embodiments, two or more stimulants may be used to identify the chemical markers. For example, chemical marker A may only emit color when exposed to stimulant I, while chemical marker B may only emit color when exposed to stimulant II. In such embodiment, the wafer may be exposed to both stimulant I and stimulant II to identify both chemical marker A and B. Although examples described herein are directed towards the identification of two types of particle defects, it will be understood that such techniques may be used to identify a plurality of particle defects, such as three or more compositions of particle defects. Further, it is noted that although particle defects may be determined by the emitted color, the term “color” as used herein refers to a spectral distribution of illumination or light and may not correspond to a specific color in the visible spectrum.

In some embodiments, the brightness of the emitted light from stimulated chemical markers may be used to determine the size of the particle defects. For example, in some embodiments, more chemical marker molecules may bind to a particle defect of a larger size such that one can identify the size of the particle based on the brightness of an emitted light from the stimulated chemical markers.

In various embodiments, methods described herein further include modifying a process recipe for fabricating the partially fabricated semiconductor wafer to reduce particle defects in the detectable areas of the partially fabricated semiconductor wafer. For example, in some embodiments, where disclosed embodiments detect locations of chemical markers on a partially fabricated semiconductor wafer and identify the particle defects to which the chemical markers are found, process operations causing those particle defects may be modified to reduce the presence of such particle defects on the semiconductor wafer. For example, an etch process or deposition process may be modified in response to identification of the composition, location, and/or size of detected particle defects.

Apparatus

Apparatuses in accordance with disclosed embodiments may be suitable for performing various methods described herein. In some embodiments, disclosed methods may be performed in a chamber with a precisely controlled stage and a chemical marker applicator.

FIG. 2 depicts a schematic illustration of an embodiment of an apparatus 200 having a detection chamber 202 for detecting defects on a semiconductor wafer. In some embodiments, a plurality of process stations in addition to apparatus 200 may be included in a multi-station processing tool, which may also include wafer transfer tool coupled to a wafer handling system for delivering a wafer to and from detection chamber 202.

Apparatus 200 includes an accurate positioning stage or wafer holder 208 capable of spinning wafer 212 at a high rate and capable of translating the wafer 212 radially. For example, as described above with respect to FIG. 1, a partially fabricated semiconductor wafer may be delivered to the detection chamber 202. The positioning stage 208 may also be connected to a heater 210 in some embodiments.

Apparatus 200 communicates with chemical marker preparation chamber 201 for delivering chemical marker (which may be a liquid or a gas or be in the form of an aerosol spray) to inlet 213, which in some embodiments may be a distribution showerhead. Chemical marker preparation chamber 201 includes a mixing vessel 204 for blending and/or conditioning chemical markers for delivery to inlet 213. For example, the mixing vessel 204 may be configured to mix chemical markers with buffers or other chemicals to generate an aqueous solution of chemical markers to deliver to the detection chamber 202. Chemical marker preparation chamber 201 may also involve delivering processes gas (such as a gaseous form of a chemical marker), carrier gas to deliver such gases via the direct gas line, and process liquid which may include an aqueous solution of chemical markers capable of being delivered to the inlet as an aerosol spray to the detection chamber 202.

As an example, the embodiment of FIG. 2 includes a vaporization point 203 for vaporizing a liquid chemical marker to be supplied to the mixing vessel 304. In some embodiments, vaporization point 203 may be a heated vaporizer. In some embodiments, a liquid chemical marker may be vaporized at a liquid injector (not shown). For example, a liquid injector may inject pulses of a liquid chemical marker into a carrier gas stream upstream of the mixing vessel 204. In some embodiments, a liquid flow controller (not shown) upstream of vaporization point 203 may be provided to control a mass flow of liquid for vaporization and delivery to detection chamber 202. In some embodiments, vaporization point 203 may be omitted such that liquid chemical marker is delivered as a liquid to the mixing vessel to generate an aqueous solution that is then delivered to the detection chamber 202.

Inlet 213 distributes chemical marker (which may be, for example, an aqueous solution) toward wafer 212. In the embodiment shown in FIG. 2, the wafer 212 is located beneath inlet 213 and is shown resting on wafer holder 208. Inlet 213 may have any suitable shape, and in some embodiments may be a nozzle. In some embodiments, inlet 213 includes more than one inlet. In some embodiments, inlet 213 includes any suitable number and arrangement of ports for distributing process gases to substrate 212. In various embodiments, the detection chamber 202 includes a door over the pump 218 such that the detection chamber 202 is capable of filling with an aqueous solution of chemical marker to form an aqueous bath in which wafer 212 may be immersed in. In various embodiments, inlet 213 may be on the side of the detection chamber 202 such that delivery of an aqueous solution of chemical marker is performed by filling the detection chamber 202 with the aqueous solution.

In some embodiments, wafer holders 208 may be raised or lowered to immerse or rinse wafer 212 in various processes.

The apparatus 200 also includes an illumination source 260 which may be configured to cause the chemical marker to fluoresce. Examples of illumination sources include a lamp and a laser. The illumination source 260 may be focused on a limited area. The apparatus 200 also includes an optics and fluorescence detector 270, such as a photomultiplier tube or linear charge-coupled detector (CCD) array.

For example, after flushing or rinsing a partially fabricated semiconductor wafer to remove “unattached” chemical marker from the wafer and pump it out of a detection chamber (such as described with respect to operation 105 above of FIG. 1), the wafer may be illuminated with a lamp or other light source to cause a chemical marker to fluoresce. A magnification system and/or sensors (such as fluorescence sensors) are then used to detect the stimulated chemical marker (e.g., fluorescence). A computer and/or controller, including a processor and memory, can track the position of the stage moving under the illumination and fluorescence sensor to record the positions on the wafer where defects are detected. The computer and/or controller also records the properties of the fluorescence signal to provide size, material, and shape information of the defect. The computer and/or controller are further described below.

Alternative embodiments include illumination apparatus for illuminating the wafer fully and imaging the fluorescence with an ultra-high resolution CCD camera for faster throughput, with possible compromise of resolution of defect location.

FIG. 2 also depicts an embodiment of a system controller 250 employed to control process conditions and hardware states of apparatus 200. System controller 250 may include one or more memory devices, one or more mass storage devices, and one or more processors. A processor may include a CPU or computer, analog and/or digital input/output connections, stepper motor controller boards, etc. A computer and/or controller 250 is coupled to components of the apparatus 200 to control wafer handling, inlet and exhaust operations for the chemical marker, parameters for the illumination source for the chemical marker, stage motion, stage position correlation and recordation, detection of the chemical marker on a wafer, and color and intensity recordation for the chemical marker fluorescence. The controller 250 may be configured to include a wafer imaging system with image analysis logic for detecting illuminated chemical markers on the wafer surface using properties of the illuminated chemical markers. In some embodiments, these properties include one or more of a spectral distribution of illumination such as color, and brightness. In some embodiments, the wafer imaging system includes a feedback mechanism for modifying process recipes in response to data collected from a tracking device of a detector 270 used to detect the location and other properties of the illuminated chemical markers. The computer and/or controller 250 may have any of the characteristics of controller 350 described below with respect to FIG. 3.

FIG. 3 provides an alternative apparatus 300 suitable for performing operations described herein. FIG. 3 includes a wafer handling system 311 with a door 309 for delivering the wafer 312 into the detection chamber 302. The detection chamber 302 may include an accurate positioning stage or wafer holder 323 which may include pins 308 capable of spinning wafer 312 at a high rate and capable of translating the wafer 312 radially. The apparatus 300 further includes an inlet 313 for introducing a chemical marker via process liquid 315 and an exhaust or outlet 318 for removing chemical marker. The apparatus 300 may be configured such that delivery of an aqueous solution of chemical marker is performed by filling the detection chamber 302 with the aqueous solution from process liquid 315 via inlet 313.

The apparatus 300 also includes an illumination source 360 which may be configured to cause the chemical marker to fluoresce and which illuminates the full wafer. Examples of illumination sources include a lamp and a laser. The apparatus 300 also includes an optics and fluorescence detector 370, such as an optics and fluorescence detector CCD planar array or camera, which images the full wafer at high resolution. A computer and/or controller 350 is coupled to components of the apparatus to control wafer handling, inlet and exhaust operations for the chemical marker, parameters for the illumination source for the chemical marker, stage motion, stage position correlation and recordation, detection of the chemical marker on a wafer, color and intensity recordation for the chemical marker fluorescence.

In some implementations, a controller 350 is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 350, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 350 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 350 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 350, in some implementations, may be a part of or coupled to a computer that is integrated with, coupled to the system, otherwise networked to the system, or a combination thereof. For example, the controller 350 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 350 receives instructions in the form of data, which specify parameters for each of the processing steps to be performed during one or more operations. It should be understood that the parameters may be specific to the type of process to be performed and the type of tool that the controller 350 is configured to interface with or control. Thus as described above, the controller 350 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller 350 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of detecting defects of a partially fabricated semiconductor wafer for semiconductor devices, the method comprising:
exposing the partially fabricated semiconductor wafer to a first chemical marker capable of selectively binding to particle defects disposed on the partially fabricated semiconductor wafer surface, undetectable by laser diffractometry and having a first composition, the chemical marker comprising a component capable of detection when exposed to a stimulant;
after exposing the wafer to the chemical marker, exposing the partially fabricated semiconductor wafer to the stimulant to form detectable areas of the partially fabricated semiconductor wafer where the first chemical marker is selectively bound to the particle defects; and
detecting the detectable areas on the surface of the partially fabricated semiconductor wafer,
wherein the surface of the partially fabricated semiconductor wafer includes less than about 2000 defects.

2. The method of claim 1, wherein the surface of the partially fabricated semiconductor wafer includes less than about 50 defects.

3. (canceled)

4. The method of claim 1, wherein the partially fabricated semiconductor wafer is exposed to the first chemical marker in an aqueous bath comprising the first chemical marker.

5. The method of claim 1, wherein the diameter of the particle defects is less than about 20 nm.

6. (canceled)

7. The method of claim 1, further comprising exposing the partially fabricated semiconductor wafer to a second chemical marker selective to particle defects having a second composition to bind the second chemical marker to the particle defects having the second composition.

8. The method of claim 7, wherein the first chemical marker emits a first spectral distribution of illumination when exposed to the stimulant, and wherein the second chemical marker emits a second spectral distribution of illumination different from the first spectral distribution of illumination when exposed to the simulant.

9. The method of claim 8, wherein the first spectral distribution of illumination is a color in the visible spectrum and the second spectral distribution of illumination is another color in the visible spectrum.

10. The method of claim 7, wherein exposing the partially fabricated semiconductor wafer to the first chemical marker and exposing the partially fabricated semiconductor wafer to the second chemical marker comprises immersing the partially fabricated semiconductor wafer in an aqueous bath comprising the first chemical marker and the second chemical marker.

11. The method of claim 7, wherein exposing the partially fabricated semiconductor wafer to the first chemical marker and exposing the partially fabricated semiconductor wafer to the second chemical marker comprises delivering an aerosol spray of a solution comprising the first chemical marker and the second chemical marker to a chamber housing the partially fabricated semiconductor wafer.

12. The method of claim 1, further comprising modifying a process recipe for fabricating the partially fabricated semiconductor wafer to reduce particle defects in the detectable areas of the partially fabricated semiconductor wafer.

13-16. (canceled)

17. An apparatus for detecting defects on a partially fabricated semiconductor wafer, the apparatus comprising:
(a) a detection chamber comprising a wafer holder for holding the partially fabricated semiconductor wafer in the detection chamber;
(b) an inlet for delivering a chemical marker to the detection chamber;
(c) an illumination source for stimulating the chemical marker to emit light;
(d) a detector for detecting emissions of the chemical marker on the surface of the partially fabricated semiconductor wafer; and
(e) a controller for controlling operations of the apparatus, the controller comprising machine-readable instructions for:
introducing the chemical marker to the detection chamber via the inlet;
removing excess chemical marker from the detection chamber after introducing the chemical marker to the detection chamber; and
turning on the illumination source to illuminate the chemical marker.

18. The apparatus of claim 17, further comprising a tracking device oriented for detecting the wafer surface while the wafer is held on the wafer holder; and a wafer imaging system comprising image analysis logic for detecting illuminated chemical markers on the wafer surface using properties of the illuminated chemical markers.

19. The apparatus of claim 18, wherein the properties comprise a spectral distribution of illumination.

20. The apparatus of claim 18, wherein the wafer imaging system further comprises a feedback mechanism for modifying process recipes in response to data collected from the tracking device.

21. The apparatus of claim 17, wherein the properties comprise brightness.

22. The apparatus of claim 17, further comprising a wafer transfer tool for inserting and removing a wafer from the detection chamber.

23. The apparatus of claim 22, wherein the apparatus is integrated with a semiconductor device fabrication apparatus, the semiconductor device fabrication apparatus comprising one or more process chambers for processing semiconductor wafers and the wafer transfer tool.

24. The apparatus of claim 17, wherein the inlet is capable of delivering an aqueous solution comprising the chemical marker to the detection chamber.

25. The apparatus of claim 17, wherein the inlet is capable of delivering an aerosol spray of the chemical marker to the detection chamber to contact the wafer with the chemical marker, wherein the inlet is positioned over the top surface of the wafer.

26. The apparatus of claim 17, wherein the detection chamber is capable of containing an aqueous bath comprising one or more chemical markers and the wafer holder is capable of immersing the wafer in the aqueous bath.
